(19) United States
(12) Patent Application Publication
(10) Pub. No.: US 2016/0242296 A1
(43) Pub. Date: Aug. 18, 2016

(54) Additive Fabrication of Single and Multi-Layer Electronic Circuits

(71) Applicant: Optomec, Inc., Albuquerque, NM (US)

(72) Inventor: Francesco Edward DeAngelis, Herndon, VA (US)

(21) Appl. No.: 15/047,350

(22) Filed: Feb. 18, 2016

Related U.S. Application Data
(60) Provisional application No. 62/117,935, filed on Feb. 18, 2015.

(51) Int. Cl. H05K 3/00; H05K 3/46; H05K 3/22; H05K 3/30; H05K 13/04; H05K 3/10; H05K 3/40

(52) U.S. Cl. CPC H05K 3/0005; H05K 3/10; H05K 3/4644; H05K 3/4038; H05K 3/306; H05K 13/0404; H05K 3/22

(57) ABSTRACT

A method and apparatus for the additive fabrication of single and multi-layer electronic circuits by using directed local deposition of conductive, insulating, and/or dielectric materials to build circuit layers incorporating conductive, insulating and/or dielectric features, including inter-layer vias and embedded electronic components. Different conductive, insulating, and/or dielectric materials can be deposited at different points in the circuit such that any section of the circuit may be tailored for specific electrical, thermal, or mechanical properties. This enables more geometric and spatial flexibility in electronic circuit implementation, which optimizes the use of space such that more compact circuits can be manufactured.

### CROSS-REFERENCE TO RELATED APPLICATIONS

This application claims priority to and the benefit of the filing of U.S. Provisional Patent Application Ser. No. 62/117,935, entitled “Additive Fabrication of Single and Multi-Layer Electronic Circuits”, filed on Feb. 18, 2015, and the specification and claims thereof are incorporated herein by reference.

### BACKGROUND OF THE INVENTION

1. Field of the Invention (Technical Field)

The present invention is a method and apparatus related to the automated fabrication of single and multi-layer electronic circuits using controlled additive deposition of multiple materials.

2. Background of the Invention

Note that the following discussion refers to a number of publications and references. Discussion of such publications herein is given for more complete background of the scientific principles and is not to be construed as an admission that such publications are prior art for patentability determination purposes. The fabrication of an electrical circuit is time consuming and costly. Typically, a printed circuit board (PCB) is designed using Computer Aided Design (CAD) software and the design is sent out to a PCB fabrication facility, where it can take several days to several weeks for fabrication while incurring costs and administrative/logistical effort. Once fabricated, the PCB is sent to an assembly facility where the electronic components are placed and soldered. This process adds an additional few days to a few weeks and incurs additional costs and administrative/logistical effort. In addition, current PCB fabrication methods place a lot of limitations on the electronic circuit design, including trace width minimums and spacings, hole sizes, via geometries, surface components, and material options. Features such as specialized high speed signal paths, different conducting and insulating material properties within a layer, embedded components, dielectric sections of a layer, and other advanced capabilities are currently not practical. The use of a PCB which consists of interconnected 2D layers all made of the same material with components only on the top and bottom surfaces to implement an electronic circuit typically results in suboptimal performance, form factors, spatial configurations, and volume usage.

### SUMMARY OF THE INVENTION

The present invention is a method for fabricating a circuit, the method comprising depositing one or more materials under computer control, the computer operating in accordance with a software circuit model which represents the circuit, thereby forming a deposit comprising material properties specified by the software circuit model; producing a plurality of sections of a circuit layer, each section comprising one or more material properties specified by the software circuit model; and producing one or more stacked circuit layers, each layer comprising material properties specified by the software circuit model, each layer corresponding to a respective layer in the software circuit model. The circuit preferably comprises one or more conductive, insulating, or dielectric electronic features, which are optionally selected from the group consisting of batteries, power sources, antennas capable of receiving radio frequency (RF) signals and providing electric power, embedded power sources, RF power sources, optical power sources, and photodiodes. The conductive electronic features are optionally selected from the group consisting of conductive signal traces, vias, and pads, and optionally comprise different materials, different shapes, different widths, and/or different thicknesses. The dielectric electronic features are optionally selected from the group consisting of embedded capacitors and dielectric sublayer sections, and optionally comprise different materials, different shapes, different widths, and/or different thicknesses. The insulating features optionally comprise embedded resistors, and optionally comprise different materials, different shapes, different widths, and/or different thicknesses. Each section preferably comprises a material property selected from the group consisting of conductive, insulating, and dielectric. A plurality of conductive sections preferably comprise different materials, different shapes, different widths, and/or different thicknesses, a plurality of insulating sections preferably comprise different materials, different shapes, different widths, and/or different thicknesses, and/or a plurality of dielectric sections preferably comprise different materials, different shapes, different widths, and/or different thicknesses. The method optionally comprises transferring heat into, out of, or around the circuit via at least one thermally conductive section. The software circuit model preferably comprises an electrical computer aided design (CAD) layout of the circuit and a layerwise three-dimensional printing representation of the circuit.

One embodiment of the method comprises forming a pocket during either producing step by not depositing material in one or more predetermined locations, and disposing a discrete electrical component in the pocket, such as by using a pick and place robotic system. This embodiment optionally comprises embedding the discrete electrical component by producing an additional layer stacked on a layer comprising the pocket. This embodiment preferably further comprises depositing first conductive pads and/or traces into the pocket for making electrical contact with pins or pads of the discrete electrical component, and preferably comprises depositing second conductive pads and/or traces along vertical walls of the pocket in order to electrically connect the first conductive pads or traces to other parts of the circuit. This embodiment preferably comprises depositing solder mask material on top of the first conductive pads and/or traces and heating the discrete electrical component in order to solder its pins or pads to the first conductive pads and/or traces.

The method optionally comprises depositing material via a deposition head connectable via a selective feed line to a plurality of material containers, via a deposition head comprising a plurality of deposition nozzles, each deposition nozzle connected to a separate material container, or via a plurality of deposition heads, each deposition head connected to a separate material container. In the last case the deposition heads optionally comprise different deposition throughputs and/or resolutions, preferably wherein one deposition head is used for rapid large area deposition and one deposition head is used for fine detail deposition. A plurality of materials may optionally be sequentially or simultaneously deposited.

The circuit optionally comprises a three-dimensional shape tailored to a predetermined mechanical footprint. Depositing one or more materials is preferably accomplished using aerosol jet deposition, ink jet printing, powder deposition, extruded liquid deposition, or wire fed solid deposition. The method optionally comprises heating one or more deposits, sections, and/or layers to sinter, densify, treat, or change a material property of the one or more heated deposits, sections, and/or layers. The one or more materials are preferably selected from the group consisting of nanopowders, nanoparticle inks, graphene, conductive inks, dielectric inks, insulating inks, powders, and wire feed stock. A plurality of circuit layers optionally have different thicknesses. The method optionally comprises depositing conductive features, dielectric features, and/or insulting features within a circuit layer. One of such conductive features optionally comprises an embedded conductive trace deposited directly under a surface conductive trace, the traces having a sufficiently small vertical separation for the traces to create a waveguide. One or more sections optionally comprise a thermally insulating material. Outer layers optionally comprise thermally insulating material for trapping internal heat produced by the circuit, thereby enabling the circuit to operate in extremely cold temperatures. The depositing step is optionally performed in a controlled atmosphere at controlled temperatures. The one or more materials are preferably initially deposited on a substrate, which can be heated, cooled and or moved relative to one or more deposition heads. Heating or cooling the substrate preferably changes the material properties and/or the stress profile of one or more circuit layers. The method optionally comprises depositing mechanical and/or structural components, which are preferably selected from the group consisting of polymers, metals, connector bodies, connectors, bases, housings, flanges, and enclosures, and can be integrated with the circuit.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention.

### BRIEF DESCRIPTION OF THE DRAWINGS

The accompanying drawings, which are incorporated into and form a part of the specification, illustrate one or more embodiments of the present invention and, together with the description, serve to explain the principles of the invention. The drawings and the dimensions therein are only for the purpose of illustrating certain embodiments of the invention and are not to be construed as limiting the invention. In the drawings:

FIG. 1 is a schematic diagram of an embodiment of the present invention.

FIG. 2 shows top and side views of a circuit produced by embodiments of the present invention.

FIG. 3 shows schematic top views of the deposition of conductive materials on a circuit layer in accordance with embodiments of the present invention.

FIG. 4 shows a side view of a multilayer circuit produced in accordance with embodiments of the present invention.

FIG. 5 illustrates an embodiment of the present invention in which a material feed line connects multiple material containers to a material deposition head comprising a single nozzle.

FIG. 6 shows the embodiment of FIG. 5 but with a multiple-nozzle material deposition head.

FIG. 7 shows the embodiment of FIG. 5 but with a plurality of deposition heads.

### DETAILED DESCRIPTION OF THE INVENTION

Embodiments of the present invention preferably greatly reduce the time, administrative/logistical effort, and potentially the cost of fabricating prototype PCB's, mitigate the limitations of current fabrication methods on circuit design, features, and performance, and provide for more spatial and geometric flexibility of the resulting electronic circuits which allows for more optimal use of space and more compact circuits. Embodiments of the present invention enable an electronic circuit to be automatically produced from a software CAD file. The apparatus to manufacture the circuit can reside in the same location as the circuit designers and produce relatively instant product without the recurring delays, administrative/logistical efforts and fabrication costs of current processes. Since preferably each part of the circuit is deposited and not made from prefabricated laminates, the conducting and insulating materials can change, and vias can be made in any fashion desired since drilling is not required. Resistive and dielectric components can be deposited directly into the layers instead of using external discrete components. Circuit layers can be made with different dimensions, materials, and thicknesses at different points, and the 3D spatial footprint of the electrical circuit can be tailored and optimized for electrical performance, form and fit, and/or overall volume minimization. As used throughout the specification and claims, the term “circuit” means a circuit, electronic circuit, circuit board, PCB, and the like.

A CAD file with the circuit design is preferably processed via software to generate a layerwise representation of the circuit that drives the additive fabrication process. Both the conductive and insulating features are deposited as contours for each feature. One or more deposition heads may be utilized and each deposition head may deposit one or more materials. One or more deposited contours can be used to create sections, and one or more sections are preferably used to create the layers of the electronic circuit. Contours are also preferably used to create the conductive traces that can be deposited on each section and layer of the circuit. Any deposited contour, section, or layer can comprise one or more materials which may impart any combination of conductive, dielectric, and/or insulating properties.

The electrical circuit is then preferably built up layer by layer, where each layer comprises sections which are created from one or more contours. Layers can have different thicknesses since they are created by additive deposition. Vias (connecting traces across the circuit layers) can be made to run vertically or diagonally, can have arbitrary shapes and geometries, and can comprise different materials so as to optimize their electrical and signal transmission characteristics for a particular function. Contours and sections of the circuit layers can also have arbitrary geometries and shapes and comprise different materials so as to achieve specific conductive, insulating, and dielectric properties and to optimize other electrical and signal transmission properties.

Any direct deposition method can be used, including but not limited to aerosol jet, ink jet, powder deposition, extruded liquid deposition, wire fed solid deposition, and the like. Materials can include nanopowders, nanoparticle inks, conductive inks or powders, multi-material wire feed stock, and/or any form of solid, liquid, or gaseous material stock with any combination of electrical, thermal, or mechanical properties.

In one embodiment of the invention, pockets are made in each layer with conductive pads or connections such that discrete electronic components can be placed inside. The embedded discrete electronic components are placed inside the pockets and conductive material is deposited such that the terminals or connection points of the discrete components are conductively coupled to the conductive pads or connections associated with the pocket for that component.

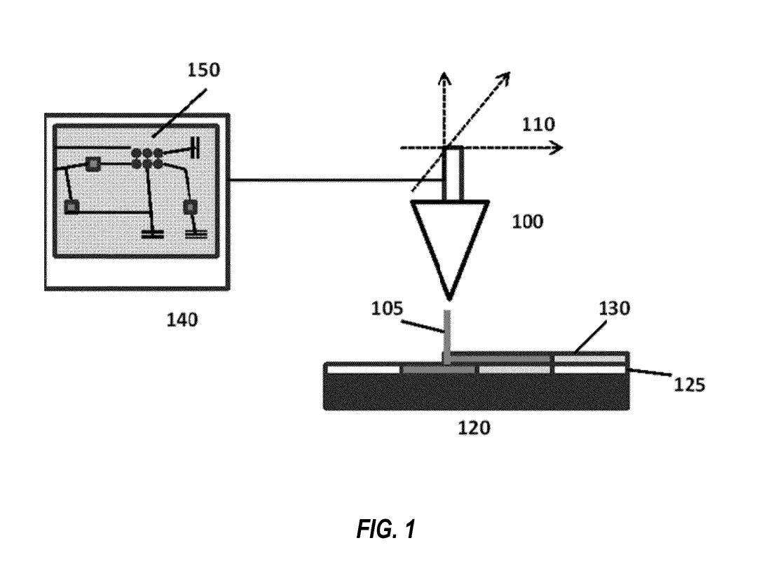

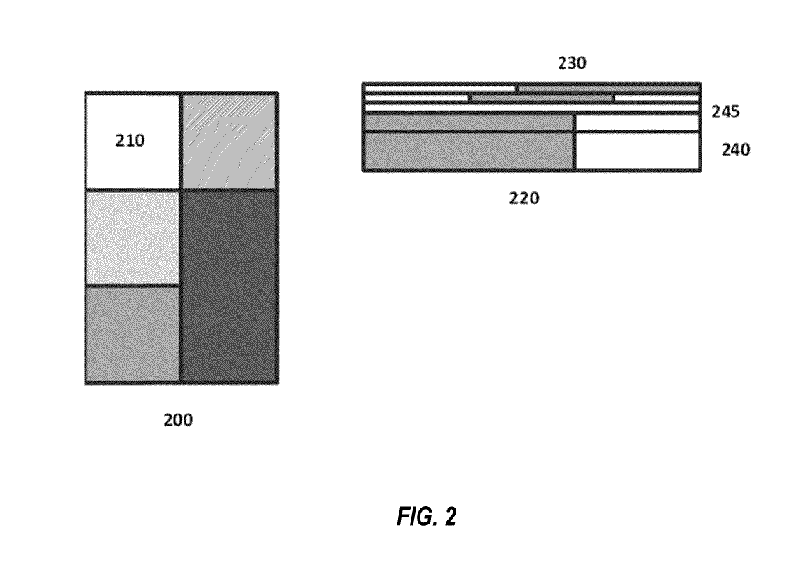

As seen in FIG. 1, computer 140 with software circuit model 150 drives selective deposition head 100 in one or more of the three spatial directions 110. Based on circuit model 150, computer 140 directs selective deposition head 100 to deposit conductive, insulating, dielectric or other material 105 onto substrate 120 or previously deposited layer 125. The different colors in layer 125 correspond to different insulating and dielectric sections whose depositions make up the layer. Section 130 is an example of a completed section on the layer currently being deposited. FIG. 2 shows a top view of circuit layer 200. Each sublayer section (for example, section 210) optionally comprises a different deposited material with tailored insulating and dielectric properties. A side view of complete multilayer circuit 220 is shown in FIG. 2, in which different layer thicknesses 240, 245 can be seen. Sublayer material section 230 is also seen from the side.

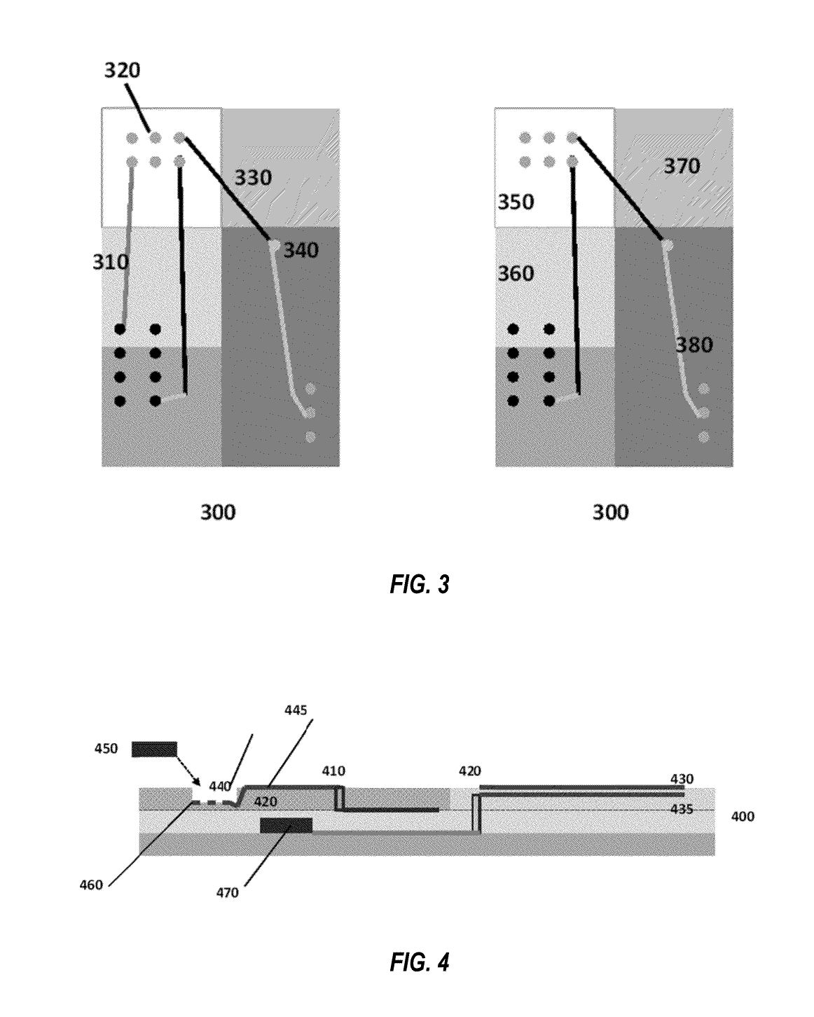

FIG. 3 shows schematic top views of the deposition of conductive materials on circuit layer 300. Component pads 320, traces 310, 330, and interlayer via 340 are formed by the deposition of conductive materials on the insulating or dielectric sections of the underlying layer (or sublayer). Conductive traces 310, 330 may comprise different conductive materials, each tailored to the specified electrical characteristics of the trace. The deposited conductive traces, pads, and vias can be of different thicknesses, widths, and arbitrary shapes, in order to impart specified conductance, impedance, frequency, and other characteristics. In the embodiment shown, sublayer sections 350, 360 comprise two different insulating materials, while sublayer sections 370, 380 comprise two different dielectric materials, which are all selected based upon the specified electrical and thermal characteristics of the circuit in those sections. For example, an insulating section with relatively high thermal conductance may be used to transport heat from a hot circuit component.

FIG. 4 shows a side view of multilayer circuit 400. Single layer via 410 and multiple layer via 420 are shown connecting conductive traces across one or more layers. Conductive trace 430 on the layer surface and conductive trace 435 embedded in the layer just beneath 430 form a waveguide with very tight internal spacing for the low loss transmission of very high frequency signals. Discrete electronic component 450 is disposed in component pocket 440, which is preferably formed by the absence of deposited material in that location. Conductive trace 445 is preferably subsequently deposited down the slope of the pocket such that it contacts conductive pads 460 inside component pocket 440, to each of which a pin or contact of inserted discrete electrical component 450 connects. A subsequent layer may be deposited over the embedded component. This pocket forming process allows discrete electronic components, such as embedded discrete electronic component 470, to be embedded within the circuit layers, resulting in smaller form factors, higher component densities, and shorter wiring paths. In an embodiment of the present invention, a pick and place robot disposes the discrete electrical components into the corresponding component pockets. A paste or flux may be deposited on conductive pads 460 to hold the components in place, while a localized heat source is used to solder the component pins or contacts to the pads.

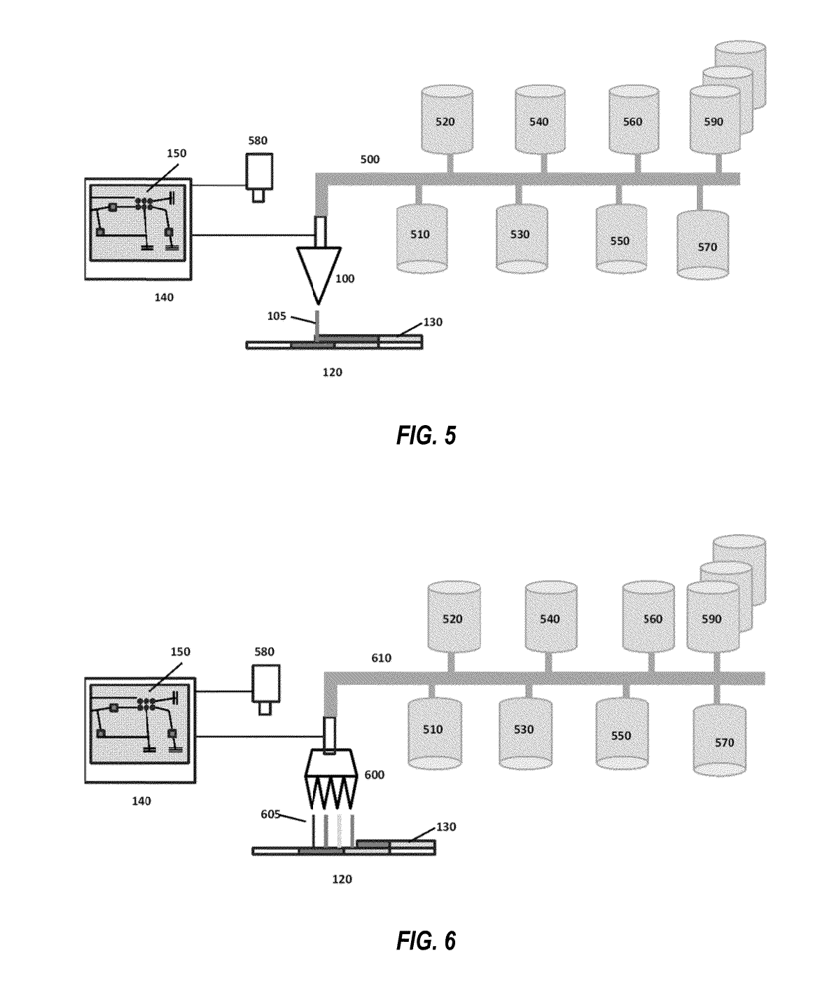

FIG. 5 illustrates an embodiment of the proposed invention in which material feed line 500 is connected to selective material deposition head 100 and to various material bins. In the embodiment shown, material containers 510, 520 contain two different insulating materials, material containers 530, 540 contain two different conductor materials, and material containers 550, 560 contain two different dielectrics. Material container 570 contains a solder mask material that can be used to coat the pads and traces associated with discrete components to facilitate soldering them onto the layer using optional heat source 580. Based on circuit model 150, computer 140 enables the various material bins to supply the appropriate material into feed line 500 and selective material deposition head 100. Selective material deposition head 100 then deposits the material onto the current layer via a deposition stream, effectively printing the various multi-material circuit layers. Material bins 590 contain materials such as polymers or metals that are used to fabricate mechanical and structural features on the electrical circuit such as connector bodies, housings, flanges, enclosures, and other features.

FIG. 6 portrays the embodiment of FIG. 5 but with multiple-nozzle selective deposition head 600. Each nozzle of multiple-nozzle selective deposition head 600 is preferably fed by a dedicated supply line in multiple line feed 610 connected to one of the material containers. In this embodiment, computer 140 simply directs each nozzle to deposit its material in the proper location via deposition streams 605.

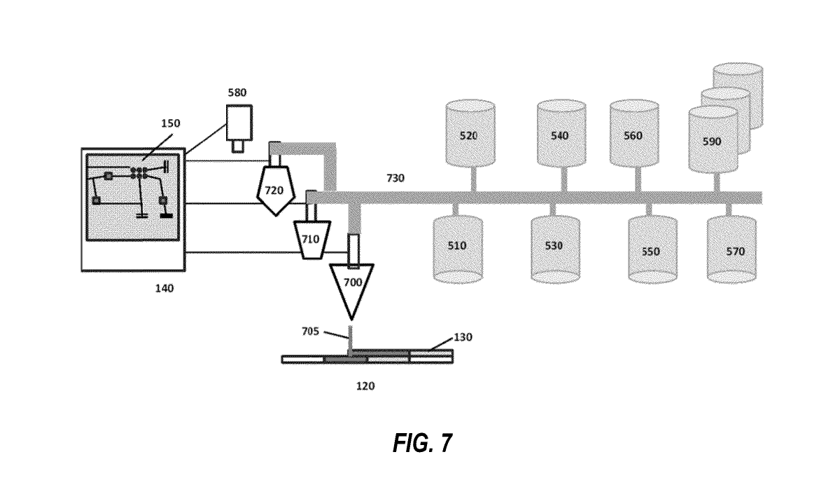

FIG. 7 portrays the embodiment of FIG. 5 except with multiple selective deposition heads 700, 710, 720. Each selective deposition head is preferably fed by a dedicated supply line in multiple line feed 730. In this embodiment, computer 140 directs each selective deposition head as required to deposit material in the proper locations on the layer. Selective deposition heads 700, 710, 720 may provide different deposition rates and resolutions; for example, one head can be used to rapidly deposit a large insulating layer, while another is used to deposit very small and/or precise conductive traces.

Although the invention has been described in detail with particular reference to the disclosed embodiments, other embodiments can achieve the same results. Variations and modifications of the present invention will be obvious to those skilled in the art and it is intended to cover all such modifications and equivalents. The entire disclosures of all patents, references, and publications cited above are hereby incorporated by reference.

What is claimed is:

1. A method for fabricating a circuit, the method comprising:
depositing one or more materials under computer control, the computer operating in accordance with a software circuit model which represents the circuit, thereby forming a deposit comprising material properties specified by the software circuit model;
producing a plurality of sections of a circuit layer, each section comprising one or more material properties specified by the software circuit model; and
producing one or more stacked circuit layers, each layer comprising material properties specified by the software circuit model, each layer corresponding to a respective layer in the software circuit model.

2. The method of claim 1 wherein the circuit comprises one or more conductive, insulating, or dielectric electronic features.

3. The method of claim 2 wherein the electronic features are selected from the group consisting of batteries, power sources, antennas capable of receiving radio frequency (RF) signals and providing electric power, embedded power sources, RF power sources, optical power sources, and photodiodes.

4. The method of claim 2 wherein the conductive electronic features are selected from the group consisting of conductive signal traces, vias, and pads.

5. The method of claim 2 wherein the conductive electronic features comprise different materials, different shapes, different widths, and/or different thicknesses.

6. The method of claim 2 wherein the dielectric electronic features are selected from the group consisting of embedded capacitors and dielectric sublayer sections.

7. The method of claim 2 wherein the dielectric electronic features comprise different materials, different shapes, different widths, and/or different thicknesses.

8. The method of claim 2 wherein the insulating features comprise embedded resistors.

9. The method of claim 2 wherein the insulating electronic features comprise different materials, different shapes, different widths, and/or different thicknesses.

10. The method and apparatus of claim 1 wherein each section comprises a material property selected from the group consisting of conductive, insulating, and dielectric.

11. The method of claim 10 wherein a plurality of conductive sections comprise different materials, different shapes, different widths, and/or different thicknesses, a plurality of insulating sections comprise different materials, different shapes, different widths, and/or different thicknesses, and/or a plurality of dielectric sections comprise different materials, different shapes, different widths, and/or different thicknesses.

12. The method of claim 1 comprising transferring heat into, out of, or around the circuit via at least one thermally conductive section.

13. The method of claim 1 wherein the software circuit model comprises an electrical computer aided design (CAD) layout of the circuit.

14. The method of claim 1 wherein the software circuit model comprises a layerwise three-dimensional printing representation of the circuit.

15. The method of claim 1 comprising forming a pocket during either producing step by not depositing material in one or more predetermined locations.

16. The method of claim 15 further comprising disposing a discrete electrical component in the pocket.

17. The method of claim 16 wherein the disposing step is performed by a pick and place robotic system.

18. The method of claim 16 further comprising embedding the discrete electrical component by producing an additional layer stacked on a layer comprising the pocket.

19. The method of claim 16 further comprising depositing first conductive pads and/or traces into the pocket for making electrical contact with pins or pads of the discrete electrical component.

20. The method of claim 19 comprising depositing second conductive pads and/or traces along vertical walls of the pocket in order to electrically connect the first conductive pads or traces to other parts of the circuit.

21. The method of claim 19 comprising depositing solder mask material on top of the first conductive pads and/or traces.

22. The method of claim 21 further comprising heating the discrete electrical component in order to solder its pins or pads to the first conductive pads and/or traces.

23. The method of claim 1 comprising depositing material via a deposition head connectable via a selective feed line to a plurality of material containers.

24. The method of claim 1 comprising depositing material via a deposition head comprising a plurality of deposition nozzles, each deposition nozzle connected to a separate material container.

25. The method of claim 24 comprising sequentially or simultaneously depositing a plurality of materials.

26. The method of claim 1 comprising depositing material via a plurality of deposition heads, each deposition head connected to a separate material container.

27. The method of claim 26 comprising sequentially or simultaneously depositing a plurality of materials.

28. The method of claim 26 wherein the deposition heads comprise different deposition throughputs and/or resolutions

29. The method of claim 28 wherein one deposition head is used for rapid large area deposition and one deposition head is used for fine detail deposition.

30. The method of claim 1 wherein the circuit comprises a three-dimensional shape tailored to a predetermined mechanical footprint.

31. The method of claim 1 wherein depositing one or more materials is accomplished using aerosol jet deposition, ink jet printing, powder deposition, extruded liquid deposition, or wire fed solid deposition.

32. The method of claim 1 comprising heating one or more deposits, sections, and/or layers to sinter, densify, treat, or change a material property of the one or more heated deposits, sections, and/or layers.

33. The method of claim 1 wherein the one or more materials are selected from the group consisting of nanopowders, nanoparticle inks, graphene, conductive inks, dielectric inks, insulating inks, powders, and wire feed stock.

34. The method of claim 1 wherein a plurality of circuit layers have different thicknesses.

35. The method of claim 1 comprising depositing conductive features, dielectric features, and/or insulting features within a circuit layer.

36. The method of claim 35 wherein one of the conductive features comprises an embedded conductive trace deposited directly under a surface conductive trace, the traces having a sufficiently small vertical separation for the traces to create a waveguide.

37. The method of claim 1 wherein one or more sections comprise a thermally insulating material.

38. The method of claim 37 comprising outer layers comprising thermally insulating material trapping internal heat produced by the circuit, thereby enabling the circuit to operate in extremely cold temperatures.

39. The method of claim 1 wherein the depositing step is performed in a controlled atmosphere at controlled temperatures.

40. The method of claim 1 wherein the one or more materials are initially deposited on a substrate.

41. The method of claim 40 further comprises heating the substrate, cooling the substrate, and/or moving the substrate relative to one or more deposition heads.

42. The method of claim 41 wherein heating or cooling the substrate changes the material properties and/or the stress profile of one or more circuit layers.

43. The method of claim 1 further comprising depositing mechanical and/or structural components.

44. The method of claim 43 wherein the mechanical and/or structural components are selected from the group consisting of polymers, metals, connector bodies, connectors, bases, housings, flanges, and enclosures.

45. The method of claim 43 comprising integrating the mechanical and/or structural components with the circuit.
